(19) United States
(12) Patent Application Publication
(10) Pub. No.: US 2018/0346325 A1
(43) Pub. Date: Dec. 6, 2018

(54) METHOD FOR MANUFACTURING A MICROELECTROMECHANICAL DEVICE AND CORRESPONDING DEVICE

(71) Applicant: TRONIC'S MICROSYSTEMS, Crolles (FR)

(72) Inventor: Joël COLLET, Saint Martin D'uriage (FR)

(21) Appl. No.: 15/780,478

(22) PCT Filed: Nov. 15, 2016
(86) PCT No.: PCT/FR2016/052963

§ 371 Date: May 31, 2018

(30) Foreign Application Priority Data
Dec. 11, 2015 (FR) 1562174

(51) Int. Cl. B81C 1/00

(52) U.S. Cl. CPC B81C 1/00333

(57) ABSTRACT

An electromechanical device includes a stack consisting of an insulating layer inserted between two solid layers. The device also includes a micromechanical structure suspended above a recess and a nanometric structure suspended above the recess. The relevant position of the nanometric structure relative to the micrometric structure is defined by the delimitation of the contours of the two structures by etching a first surface of a substrate consisting of a solid layer so as to obtain trenches that define the structures.

### TECHNICAL FIELD

The present disclosure relates to the field of electromechanical systems formed from elements of micrometric dimensions, also called MEMS (acronym for Micro-Electromechanical System) and elements of nanometric dimensions also called NEMS (acronym for Nano-Electromechanical System). More particularly, the present disclosure concerns a method of fabricating such a system.

### BACKGROUND

Typically, to reduce the size of electromechanical systems while ensuring good sensitivity of measurements, it is advantageous to combine micro-electromechanical elements and nano-electromechanical elements. Such electromechanical systems are now known as M&NEMS, for Micro-and Nano-ElectroMechanical Systems.

Among such M&NEMS systems are force sensors, such as accelerometers, gyrometers or magnetometers. Such force sensors are typically in the form of devices comprising a movable mass held mechanically by deformable elements such as springs. Moreover, the movable mass is mechanically coupled to deformable structures such as measurement beams used to measure the movements of the mass. These measurement beams can for example be strain gauges or resonators. The mass and beam assembly is held suspended above a cavity.

For example, in the case of an accelerometer, when the sensor is moved, the movable mass experiences an inertial force and induces a stress on the measurement beam. Typically, in the case of a resonator type measurement beam, the stress applied by the mass induces a variation of the frequency of the resonator, and in the case of a variable resistance type measurement beam, the stress applied by the mass induces a variation of the electrical resistance. The acceleration is deduced from these variations.

It is understandable, therefore, that it is advantageous to combine a movable mass of micrometric thickness and a measurement beam of nanometric thickness. In particular, a significant mass of the movable element makes it possible to maximize the inertial force and thus induce sufficient stress on the measurement beam. Moreover, by preferring a beam of minimal thickness, the stress applied by the mass on the beam is maximized. Thus, such an arrangement also has the advantage of increasing the sensitivity of the force sensor.

The document EP 1,840,582 presents such a force sensor, namely a sensor in which the movable mass has a thickness that is greater than that of the beam, and further proposes a method of fabricating such a sensor based on SOI (Silicon On Insulator) technology.

According to the first fabricating method described in this document, the strain gauge is first etched in a surface layer of a SOI substrate, then covered with a protection. A silicon epitaxy is then produced on this surface layer so as to obtain a layer of desired thickness for the production of the test body. However, the epitaxial growth technique is difficult and expensive to carry out, and very significant silicon layer thicknesses cannot be obtained with it. Because of this limitation, it is difficult to obtain an optimal sizing of the test body, and thus of the mass thereof, to maximize the stress applied to the gauge.

According to a second fabrication method described in this document, the movable mass is first etched in an SOI substrate. A polycrystalline silicon layer of nanometric thickness is then deposited for the purpose of forming a strain gauge. However, the small thickness of the polycrystalline silicon layers is still difficult to control, and its electrical and mechanical properties are inferior to those of a monocrystalline silicon layer. Moreover, the deposit of such a thin layer can be subject to stresses such as deformations, which can affect the performance of the gauge. It is therefore difficult by this method to obtain a gauge having mechanical and electrical characteristics that optimize the sensitivity of the sensor.

Another solution can consist in utilizing two different SOI substrates to form separately the movable mass and the gauge, then to seal the two substrates together. However, a misalignment of the different elements, particularly between the mobile mass, the gauge and the cavity, is likely to occur during sealing, increasing the risk of altering the overall sensitivity of the sensor.

### SUMMARY OF THE DISCLOSURE

In this context, a purpose of the present disclosure is particularly to propose a solution for fabricating electromechanical devices without the aforementioned limitations.

Thus, an object of the disclosed embodiments is a method of fabricating an electromechanical device comprising at least one micromechanical structure (or active body) and at least one nanometric structure (or gauge) suspended above a cavity.

According to the disclosed embodiments, the fabrication method comprises the definition of the contours of the micromechanical structure and of the nanometric structure by etching a first surface of a first substrate so as to obtain trenches which define the two structures. The first substrate comprises a single bulk layer.

The fabrication method then comprises the formation of a temporary cavity disposed beneath the structure by isotropic etching of trenches defining the nanometric structure so as to form the nanometric structure.

To facilitate the transport of said temporary structure, the fabrication method comprises the sealing of the first surface of the first substrate with a second substrate; this step is followed by a thinning of the first substrate. Preferably, the second substrate is formed from at least one bulk layer and one insulating layer.

This sealing is followed by the formation of the cavity in the first substrate, by etching of a second surface of the first substrate. The cavity is then closed by sealing the second surface of the first substrate with a third substrate. Said third substrate is formed from a bulk layer and an insulating layer in direct contact with the second surface of the first substrate.

The transport of this temporary structure can then be performed by the third substrate and the second substrate is eliminated. Finally, the first surface of the first substrate is etched so as to open the cavity and form the micromechanical structure.

The term “micromechanical structure” refers to a structure for which the thickness is of micrometric dimensions. The term “nanometric structure” refers to a structure for which one of the designs is of nanometric width, for example the width.

Furthermore, the thickness of the nanometric structure can be of micrometric dimensions.

Thus, the fabrication method of the disclosed embodiments is a simple, inexpensive solution that enables the alignment problem mentioned above to be overcome, since the respective positioning of the micrometric and nanometric structures is achieved simultaneously by an etching of the contours of both structures in the same single layer substrate, commonly called “bulk.” This is made possible by the use of two other very different substrates, one serving as support substrate to define the bottom of the cavity, the other serving as “handle” substrate or temporary support (“carrier”) substrate.

Another advantage contributed by this fabrication method is that the bottom of the cavity of the electromechanical device thus obtained is covered with an insulating layer, generally an oxide layer. The presence of said insulating layer has the particular advantage of preventing the appearance of irregularities resulting from the chemical process used to clear the cavity. In other words, because of said insulating layer, the bottom of the cavity will not be attacked during the etching process used to create the cavity. The resulting device is therefore cleaner, i.e. containing less dust that could block the active body or interfere with measurements. Moreover, the risk of degassing from the internal surfaces of the cavity is reduced, which provides a stable pressure over time in the housing in which the device is enclosed.

Advantageously, the fabrication method can further comprise, prior to the sealing of the first substrate with the second substrate, the creation of alignment marks on the first surface of the first substrate.

Typically, said alignment marks are used as indicators to ensure the correct positioning of the masks utilized in the etching methods used to produce the cavity and the micromechanical structure.

In particular, said alignment marks can be in the form of predefined structures (verniers, squares, bar codes, etc.) and can be obtained in conventional ways, for example by an etching technique.

According to one embodiment, the method further comprises, prior to the sealing of the first substrate with the second substrate and consecutive to the creation of alignment marks, the protection of the first surface of the first substrate by an oxidation step intended to form an oxide layer on the first surface, then by a step of depositing a nitride layer on the oxide layer. In this embodiment, the step of definition of the contours of the micromechanical structure and of the nanometric structure includes etching the oxide layer and the nitride layer. This protection allows the external appearance of the micrometric and nanometric structures to be protected.

According to one embodiment, the method further comprises, prior to the formation of the temporary cavity and consecutive to the definition of the contours of the micromechanical structure and the nanometric structure, the protection of the trenches by the deposit of a second nitride layer. In this embodiment, the step of formation of the temporary cavity is preceded by a step of etching the nitride present in the bottom of the trenches defining the nanometric structure. This protection enables the contours of the micrometric and nanometric structures to be protected.

According to one embodiment, the method further comprises, prior to the sealing of the first surface of the first substrate with a second substrate, an oxidation of the silicon so as to fill the temporary cavity disposed beneath the nanometric structure. Said oxidation makes it possible to protect the surface of the nanometric structure facing the cavity for the subsequent steps.

According to one embodiment, the formation of the cavity in the first substrate, by etching a second surface of the first substrate, includes a first etching having the depth of the cavity near the micrometric structure and a second etching having the depth of the cavity near the nanometric structure. Advantageously, the second etching extends to the temporary cavity having the silicon oxide.

According to one embodiment, the method further comprises, prior to the creation of the cavity, the thinning of the first substrate.

In effect, the bulk layer of the first substrate used can typically have an initial thickness of several hundred microns, for example 450 μm. Furthermore, the useful thickness of the bulk layer for creation of the cavity and micromechanical structure is for example less than around a hundred microns, for example 50 μm. In this case, it is then necessary to provide a prior step of thinning this bulk layer to avoid etchings that are too deep. Said thinning makes it possible, therefore, to obtain a residual thickness of the first substrate that is substantially equal to the predetermined thickness of the micromechanical structure plus the predetermined depth of the cavity. Said residual thickness typically corresponds to said useful thickness. In practice, said thinning can be obtained by grinding or chemical etching, mechanical-chemical etching or dry etching.

According to one embodiment, the method further comprises, simultaneous with the creation of the cavity, the formation of at least one stop extending from the first substrate towards the third substrate.

In practice, the creation of the cavity and of the stop (or stopper) can be obtained by:

a first lithography then a first etching to partially etch the cavity in the first substrate and to define the height of the stop. The depth of said first etching is therefore substantially equal to the desired distance (for example 1 μm) between the free end of the stop and the insulating layer of the third substrate defining the bottom of the cavity; and

a second lithography and a second etching in order to definitively form the stop as well as the cavity.

Thus, the stop is secured, not with the bottom of the cavity, but is secured to the active body and particularly to the micrometric structure.

An object of the disclosed embodiments is also an electromechanical device comprising:

a stack formed from an insulating layer interposed between two bulk layers,

a micromechanical structure suspended above a cavity, and

a nanometric structure suspended above the cavity.

In practice:

the nanomechanical structure can be a deformable measurement element such as a strain gauge, a deformable membrane, or a nanomechanical resonator;

the micromechanical structure can be formed from a movable mass coupled to deformable elements such as springs, a membrane, or nanomechanical structures;

the nanomechanical structure can have a thickness of between 100 nm and 10 μm;

the micromechanical structure can have a thickness less than 100 μm and more than 5 μm;

the bulk layers and the thin layer are preferably of silicon and the insulating layers are preferably of oxide.

### BRIEF DESCRIPTION OF FIGURES

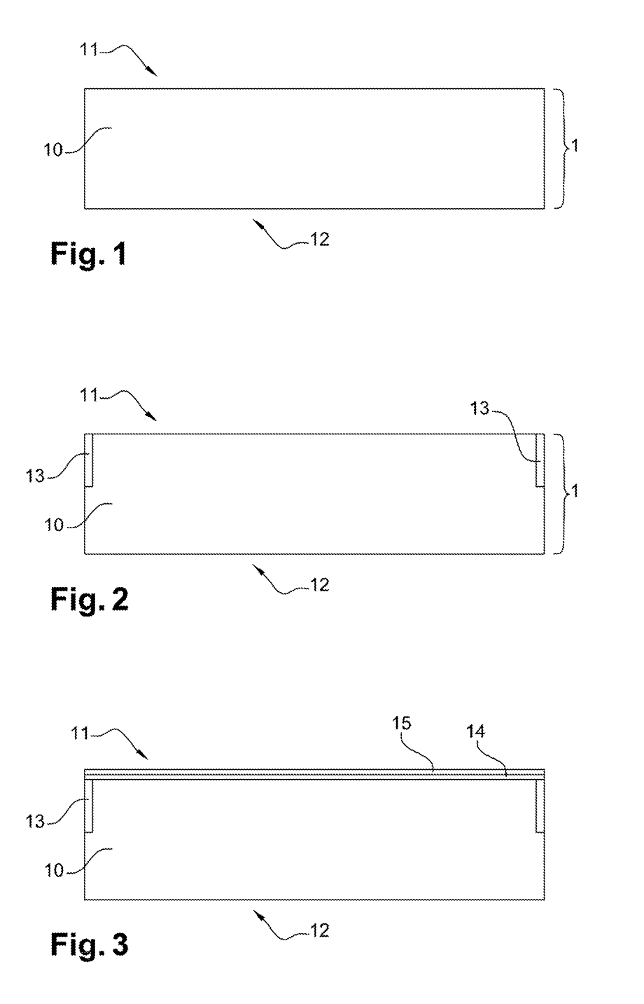

Other characteristics and advantages will be seen clearly from the following description, provided for information and without limitation, with reference to FIGS. 1 to 12 which are schematic views illustrating the steps of the method of fabricating an electromechanical device incorporating an active structure of micrometric dimensions and an active structure of nanometric dimensions, according to one embodiment.

### DETAILED DESCRIPTION OF PARTICULAR EMBODIMENTS

FIGS. 1 to 12 illustrate the different steps of a method of fabricating an electromechanical device according to one embodiment. In particular, the electromechanical device to be obtained is illustrated in FIG. 12 and incorporates in particular a micromechanical structure 60 of predetermined thickness, for example 20 μm, suspended above a cavity 4 of predetermined depth, for example 5 μm. For example, the micromechanical structure 60 is an active body formed from a mobile mass. The electromechanical device also incorporates a nanometric structure 7 of predetermined thickness, for example 250 nm, suspended above the cavity 4. For example, the nanometric structure 7 is a strain gauge intended to measure the stresses on the mobile mass so as to evaluate a displacement of the electromechanical device.

In one variant, the electromechanical device can further comprise a stop 5 which extends from the micromechanical structure 60 towards the bottom of the cavity 4. For example, the spacing between the free end of the stop 5 and the bottom of the cavity 4 is substantially equal to 1 μm.

More precisely, the cavity 4, the micromechanical structure 60 and the nanomechanical structure 7 are produced by etching, in the same monolayer substrate that corresponds to the first substrate 1 illustrated in FIG. 1. In the example of FIG. 1, two nanometric structures 7 are disposed at the ends of a plurality of micromechanical structures 60. As a variant, one or more nanometric structures 7 can be disposed at the center of the micromechanical structures 60.

Said first substrate 1, commonly called “bulk,” is therefore only formed from a bulk layer 10, for example a layer of silicon 450 μm thick, and has two opposite surfaces, namely a first surface 11 and a second surface 12.

First, to ensure correct positioning of the masks that will be used during etching, alignment marks 13 are created (FIG. 2) on the first surface 11 of said first substrate 1. The depth of said alignment marks 13 is greater than the total thickness of the micromechanical structure 60, of the nanometric structure 7 and of the cavity 4.

Then, the first surface 11 is protected by an oxidation step intended to form an oxide layer 14 on the first surface 11, then by a step of depositing a nitride layer 15 on the oxide layer 14 (FIG. 3). For example, the oxidation step can be accomplished by a thermal process. For example, the step of depositing the nitride layer 15 can be accomplished by low-pressure chemical vapor deposition (LPCVD).

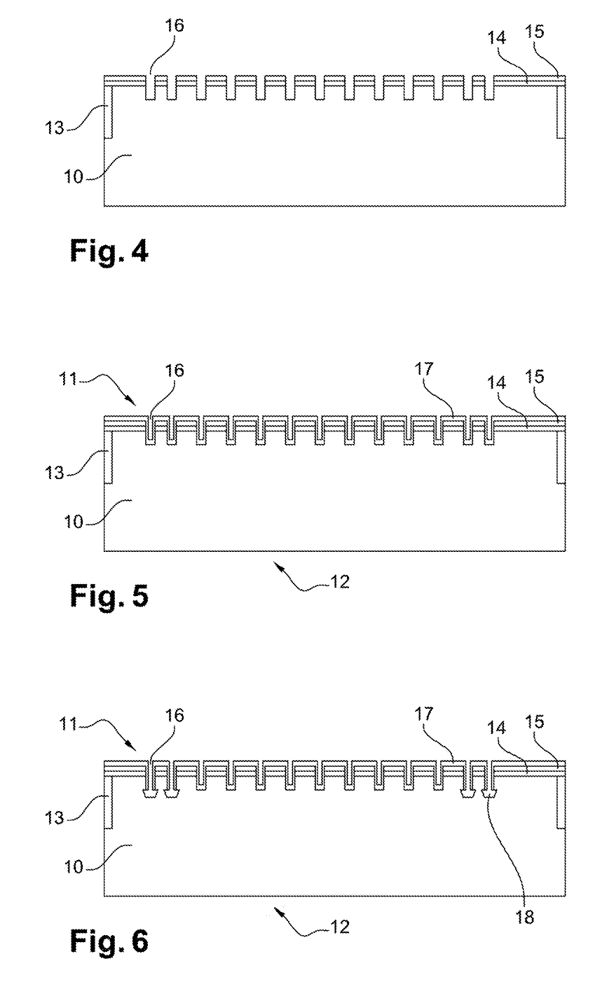

The next step consists in defining the contours of the micromechanical structure 60 and of the nanometric structure 7 (FIG. 4). To do this, trenches 16 are produced by lithography in the nitride layer 15, in the oxide layer 14 and in a portion of the silicon layer 10. Preferably, the silicon layer 10 is etched to a depth substantially equal to 450 nm. This step makes it possible to precisely align the micromechanical structure 60 and the nanometric structure 7 because they are produced from the same mask.

The trenches 16 thus formed are then protected by the deposition of a second nitride layer 17 (FIG. 5) on the first nitride layer 15 and in the trenches 16. For example, the step of depositing the second nitride layer 17 can be achieved by an LPCVD chemical deposition process.

The nitride 15 present in the bottom of the trenches 16 defining the nanometric structure 7 is then removed by directive etching, for example by reactive ion etching, also known as RIE.

Then, the silicon present in the silicon layer 10 defining the nanometric structure 7 is etched by isotropic etching so as to etch beneath the nanometric structure 7 (FIG. 6) in the same manner in all directions.

Isotropic etching attacks the substrate in several directions. Isotropic etching can be achieved by reactive ion etching, also known as RIE, or chemical etching. Said isotropic etching makes it possible to form a temporary cavity 18 disposed beneath the nanometric structure 7.

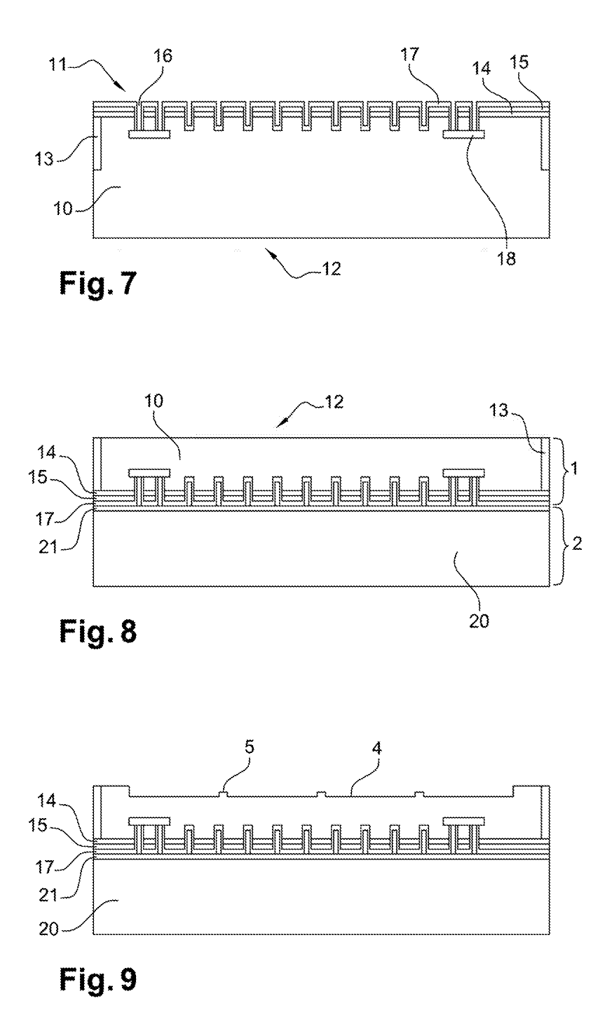

Thermal oxidation of the silicon in the trenches 16 not containing nitride 17 is then performed until the silicon oxide fills the temporary cavity 18 disposed beneath the nanometric structure 7 (FIG. 7) and totally replaces the silicon located beneath the future gauge.

To facilitate the handling of said first substrate 1, a second substrate 2 is sealed to said first substrate 1. Said second substrate 2 is formed from a bulk layer 20, for example a layer of silicon 450 μm thick, and an insulating layer 21, for example a layer of oxide 1 μm thick. In particular, the insulating layer 21 of the second substrate is placed in direct contact with the first surface 11 of the first substrate 1. At this stage, the alignment marks 13 that were previously made are covered by said second substrate 2. Since the cavity 4, the micromechanical structure 60, and the nanometric structure 7 must be produced in said first substrate 1, a thinning of said first substrate 1 is performed (FIG. 8). More precisely, the thinning is such that the residual thickness of said first substrate 1 corresponds substantially to the predetermined thickness of the micromechanical structure 60 added to the predetermined depth of the cavity 4. Conventionally, said thinning can for example be achieved by grinding or chemical etching.

The alignment marks 13 are thus freed during the thinning step and are made visible on the side of the second surface 12 of the first substrate 1.

In the case when a stop 5 is provided, a lithography and a single etching (FIG. 9) are performed in order to form the stop 5 and to define the depth of the cavity 4 in the first thinned substrate 1. At this stage, the dimensions of the cavity 4 and of the stop 5 already correspond to the final desired dimensions beneath the micrometric structure 60. Moreover, the thickness of the remaining portion of the first substrate facing the cavity 4 is substantially equal to the final desired thickness of the micromechanical structure 60. Thus, the cavity 4, the stop 5 and the thickness of the micromechanical structure 60 are defined by this etching.

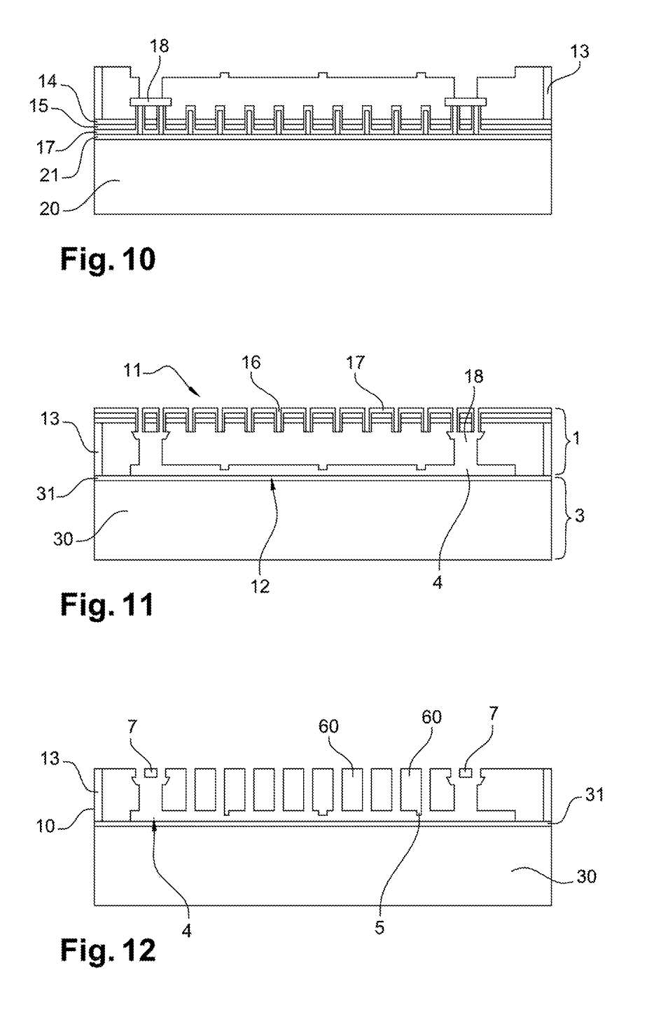

A lithography and a deep etching are then performed (FIG. 10) at the nanometric structure 7 until reaching the oxide previously formed in the temporary cavity 18 situated beneath the nanometric structure 7.

The next step consists in sealing a third substrate 3 with the first substrate 1 to close the cavity 4 thus formed. Said third substrate 3 is also formed from a bulk layer 30, for example a layer of silicon more than 300 μm thick, and an insulating layer 31, for example a layer of oxide 1 μm thick. Furthermore, said sealing is such that the insulating layer 31 of said third substrate 3 is placed in direct contact with the second surface 12 of the first substrate 1.

The second substrate 2 is then eliminated, and two etchings are performed (FIG. 11). A first etching allows the oxide present in the temporary cavity 18 beneath the nanometric structure 7 to be eliminated. Said etching can be achieved by a wet chemical etching technique.

The second etching allows the nitride layer 17 present in the bottom of the trenches 16 to be eliminated. Preferably, the second etching is achieved by directive etching, for example by reactive ion etching, also known as RIE.

A deep etching is then performed at the micro mechanical structure 60 in order to reach the cavity 4. The oxide 14 and nitride 15, 17 protection layers are then eliminated to release the micromechanical 60 and nanometric structure 7.

The electromechanical device thus obtained (FIG. 12) therefore comprises a stack formed from an insulating layer 31 interposed between two bulk layers 10, 30. The cavity 4, the micromechanical structure 60, and the nanometric structure 7 are produced in one 10 of the two bulk layers of the stack, and the insulating layer 31 forms the bottom of the cavity 4.

The fabrication method presented is therefore simple and overall less expensive even though three substrates are used, since it uses neither an SOI substrate nor epitaxy. In particular, it makes it possible to obtain M&NEMS type electromechanical devices that are smaller and more efficient, wherein the cavity, the micromechanical structure and the nanometric structure are produced in a single, single-layer substrate. Moreover, the working life of such a device is improved thanks to the insulating layer at the bottom of the cavity which prevents the appearance of irregularities in the bottom of the cavity during etchings. Finally, the proposed solution also offers the possibility of adapting the thickness of the micrometric and nanometric structures by simple adjustment of etching equipment.

1. A fabrication method of an electromechanical device comprising at least one micromechanical structure and at least one nanometric structure suspended above a cavity, the method comprising:
the definition of the contours of the micromechanical structure and of the nanometric structure by etching a first surface of a first substrate, formed from a bulk layer, so as to obtain trenches defining the two structures;
the formation of a temporary cavity disposed beneath the structure by isotropic etching of trenches defining the nanometric structure so as to form the nanometric structure;
the sealing of the first surface of the first substrate with a second substrate;
the formation of the cavity in the first substrate, by etching of a second surface of the first substrate;
the closing of the cavity by sealing the second surface of the first substrate with a third substrate, the third substrate being formed from a bulk layer and an insulating layer in direct contact with the second surface of the first substrate;
the elimination of the second substrate; and
the etching of the first surface of the first substrate so as to open the cavity and form the micromechanical structure.

2. The fabrication method according to claim 1, further comprising, prior to the sealing of the first substrate with the second substrate, the creation of alignment marks on the first surface of the first substrate.

3. The fabrication method according to claim 2, further comprising, prior to the sealing of the first substrate with the second substrate and consecutive to the creation of alignment marks, the protection of the first surface of the first substrate by an oxidation step intended to form a layer of oxide on the first surface, then by a step of depositing a nitride layer on the oxide layer, and the step of definition of the contours of the micromechanical structure and of the nanometric structure comprising an etching of the oxide layer and of the nitride layer.

4. The fabrication method according to claim 1, further comprising, prior to the formation of the temporary cavity and consecutive to the definition of the contours of the micromechanical structure and of the nanometric structure, the protection of the trenches by the deposition of a second nitride layer, the step of formation of the temporary cavity being preceded by a step of etching the nitride present in the bottom of the trenches defining the nanometric structure.

5. The fabrication method according to claim 1, further comprising, prior to the sealing of the first surface of the first substrate with a second substrate, an oxidation of the silicon so as to fill the temporary cavity disposed beneath the nanometric structure.

6. The fabrication method according to claim 1, wherein the formation of the cavity in the first substrate, by etching a second surface of the first substrate, includes a first etching having the depth of the cavity near the micrometric structure and a second etching having the depth of the cavity near the nanometric structure.

7. The fabrication method according to claim 5, wherein the second etching extends to the temporary cavity having the silicon oxide.

8. The fabrication method according to claim 1, further comprising, prior to the creation of the cavity, the thinning of the first substrate.

9. The fabrication method according to claim 1, further comprising, simultaneous to the creation of the cavity, the formation of at least one stop extending from the first substrate towards the third substrate.

10. An electromechanical device produced by a fabrication method according to claim 1, the electromechanical device comprising:
a stack formed from an insulating layer interposed between two bulk layers,
a micromechanical structure suspended above a cavity and
a nanometric structure suspended above the cavity.
